(19) United States
(12) Patent Application Publication
(10) Pub. No.: US 2012/0002371 A1
(43) Pub. Date: Jan. 5, 2012

(54) ELECTRONIC DEVICE WITH HEAT DISSIPATION APPARATUS

(75) Inventors: ZEU-CHIA TAN, Tu-Cheng (TW); YAO-TING CHANG, Tu-Cheng (TW)

(73) Assignee: HON HAI PRECISION INDUSTRY CO., LTD., Tu-Cheng (TW)

(21) Appl. No.: 12/855,056

(22) Filed: Aug. 12, 2010

(30) Foreign Application Priority Data
Jun. 30, 2010 (TW) 99121554

(51) Int. Cl. H05K 7/20

(52) U.S. Cl. 361/709

(57) ABSTRACT

An electronic device includes an enclosure, a circuit board disposed within the enclosure, a heat sink, and a thermally conductive member. A heat-generating electronic component is fixed to the circuit board. The heat sink is in contact with the heat-generating electronic component. Two ends of the thermally conductive member are respectively fixed to the enclosure and the heat sink.

### BACKGROUND

1. Technical Field

The present disclosure relates to electronic devices, and particularly, to an electronic device having a heat dissipation apparatus for cooling heat-generating electronic components of the electronic device.

2. Description of Related Art

With the development of the large scale integration semiconductor industry, the density of integration of an integrated circuit chip (the core component of many electronic systems) is becoming greater and greater, as a result, the chip can run at unprecedented high speeds and generates large amounts of heat. The heat must be quickly and efficiently removed from around the chip to maintain the chip at safe operating temperatures.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of an electronic device.

FIG. 2 is an assembled, isometric view of the electronic device of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

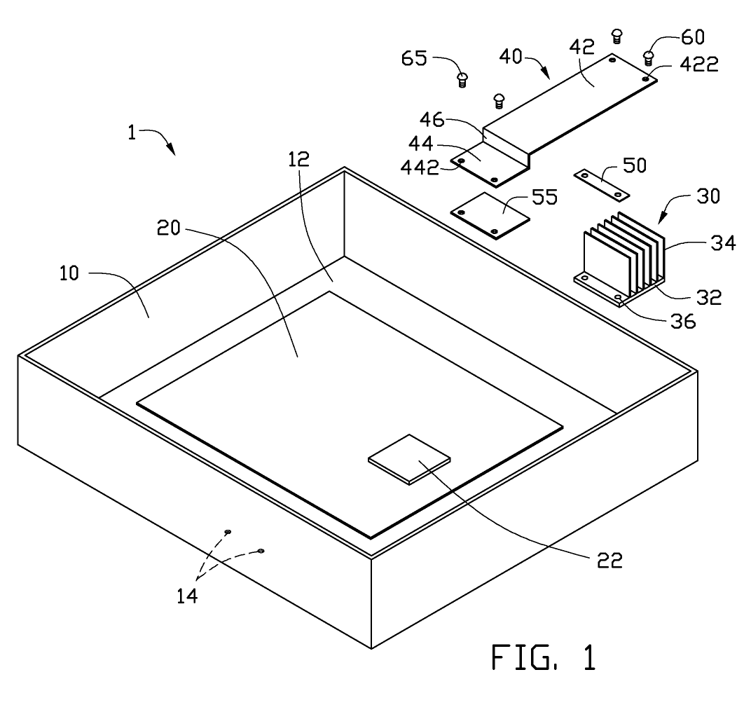

Referring to FIG. 1, an exemplary embodiment of an electronic device 1 includes an enclosure 10, a circuit board 20 disposed within the enclosure 10, a heat sink 30, a thermally conductive member 40, and two thermal pads 50 and 55. In this embodiment, thickness of the two thermal pads 50 and 55 is about 0.5 millimeters (mm), and the two thermal pads 50 and 55 are made of thermal interface material (TIM), a thermal conductive coefficient of which is about 6 watts per meter kelvin (w/(m·k)).

The circuit board 20 is attached to a side panel 12 of the enclosure 10. A plurality of installation holes 14 is defined in the side panel 12, adjacent the circuit board 20. A heat-generating electronic component 22, such as a central processing unit, is fixed to the circuit board 20.

The heat sink 30 includes a thermally conductive base 32, and a plurality of thermally conductive fins 34 extending substantially perpendicularly from a top of the base 32. A plurality of fixing holes 36 is defined in an end of the base 32.

The thermally conductive member 40 is plate-shaped, and includes a long first conductive segment 42, a short second conductive segment 44, and a coupling segment 46 perpendicularly connected between the first and second conductive segments 42 and 44. A plurality of first holding holes 422, corresponding to the fixing holes 36 of the base 32, is defined in a free end of the first conductive segment 42, opposite to the second conductive segment 44. A plurality of second holding holes 442, corresponding to the installation holes 14 of the side panel 12, is defined in a free end of the second conductive segment 44, opposite to the first conductive segment 42. In this embodiment, thickness of the thermally conductive member 40 is about 0.8 mm, and the thermally conductive member 40 is made of thermally conductive material, a thermal conductive coefficient of which is about 120 w/(m·k)).

The two thermal pads 50 and 55 are made of thermal glue, and respectively correspond to the first and second conductive segments 42 and 44. A plurality of through holes (not labeled) is defined in the thermal pads 50 and 55, respectively corresponding to the first and second holding holes 422 and 442 of the first and second conductive segments 42 and 44.

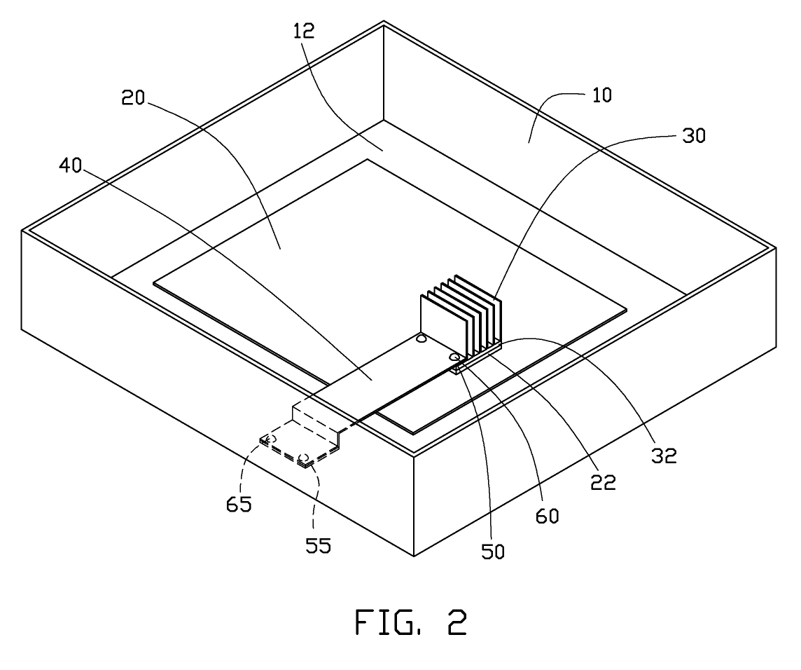

Referring to FIGS. 1 and 2, in assembly, a bottom of the base 32 of the heat sink 30 is attached to the heat-generating electronic component 22 of the circuit board 20, and the heat sink 30 may be secured to the circuit board 20 by traditional installation means. The first conductive segment 42 of the thermally conductive member 40 is placed on the base 32 of the heat sink 30, and the thermal pad 50 is sandwiched between the first conducive segment 42 and the base 32. A plurality of fasteners 60 extends through the corresponding first holding holes 422 of the first conducive segment 42, and the corresponding through holes of the thermal pad 50, to engage in the corresponding fixing holes 36 of the base 32. Thus, the first conductive segment 42 is fixed to the base 32. The second conductive segment 44 of the thermally conductive member 40 is positioned on the side panel 12 of the enclosure 10. The thermal pad 55 is sandwiched between the second conducive segment 44 and the side panel 12 of the enclosure 10. A plurality of fasteners 65 extends through the corresponding second holding holes 442 of the second conducive segment 44, and the corresponding through holes of the thermal pad 55, to engage in the corresponding installation holes 14 of the side panel 12. Thus, the second conductive segment 44 is fixed to the enclosure 10.

In use, heat generated by the heat-generating electronic component 22 is spread to the base 32 of the heat sink 30. Heat from the base 32 is dissipated not only by the fins 34 of the heat sink 30, but also by the side panel 12 of the enclosure 10 through thermal conduction of the thermally conductive member 40. Because the surface area of the enclosure 10 is large, the heat generated by the heat-generating electronic component 22 is quickly absorbed, thereby improving heat dissipation efficiency. The thermal pads 50 and 55 provide good thermal contact with surfaces of the thermally conductive member 40 and the heat sink 30 and enclosure 10.

In other embodiments, the first and second conductive segments 42 and 44 of the thermally conductive member 40 are directly fixed to the heat sink 30 and the enclosure 10 by other means, such as glue, and the thermal pads 50 and 55 are made of other high-performance thermal interface material, such as thermal grease.

It is to be understood, however, that even though numerous characteristics and advantages of the embodiments have been set forth in the foregoing description, together with details of the structure and function of the embodiments, the present disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. An electronic device comprising:
an enclosure;
a circuit board disposed within the enclosure, with a heat-generating electronic component fixed on the circuit board;
a heat sink in contact with the heat-generating electronic component; and
a thermally conductive member, two ends of the thermally conductive member respectively fixed to the enclosure and the heat sink.

2. The electronic device of claim 1, wherein thermal interface material is sandwiched between the enclosure and the corresponding end of the thermally conductive member.

3. The electronic device of claim 2, wherein the thermal interface material is in a form of a thermal pad.

4. The electronic device of claim 3, wherein thickness of the thermal pad is about 0.5 millimeters (mm)

5. The electronic device of claim 2, wherein the thermal interface material is thermal glue.

6. The electronic device of claim 2, wherein the thermal interface material is thermal grease.

7. The electronic device of claim 2, wherein a thermal conductive coefficient of the thermal interface material is about 6 watts per meter kelvin (w/(m·k)).

8. The electronic device of claim 1, wherein thermal interface material is sandwiched between the heat sink and the corresponding end of the thermally conductive member.

9. The electronic device of claim 8, wherein the thermal interface material is in a form of a thermal pad.

10. The electronic device of claim 9, wherein thickness of the thermal pad is about 0.5 millimeters (mm)

11. The electronic device of claim 8, wherein the thermal interface material is thermal glue.

12. The electronic device of claim 8, wherein the thermal interface material is thermal grease.

13. The electronic device of claim 8, wherein a thermal conductive coefficient of the thermal interface material is about 6 watts per meter kelvin (w/m·k)).

14. The electronic device of claim 1, wherein the thermally conductive member is made of thermally conductive material.

15. The electronic device of claim 14, wherein a thermal conductive coefficient of the thermally conductive material is about 120 watts per meter kelvin (w/m·k)).

16. The electronic device of claim 1, wherein the thermally conductive member is plate-shaped.

17. The electronic device of claim 16, wherein thickness of the thermally conductive member is about 0.8 millimeters (mm)

18. The electronic device of claim 16, wherein the thermally conductive member comprises a first conductive segment fixed to the heat sink, a second conductive segment fixed to the enclosure, and a coupling segment perpendicularly connected between the first and second conductive segments.

19. The electronic device of claim 18, wherein the heat sink includes a thermally conductive base, and a plurality of thermally conductive fins extending from a top of the base; a plurality of fixing holes is defined in the base, a plurality of first holding holes is defined in the first conductive segment, and a plurality of fasteners extends through the corresponding first holding holes to engage in the corresponding fixing holes.

20. The electronic device of claim 18, wherein a plurality of installation holes is defined in the enclosure, a plurality of second holding holes is defined in the second conductive segment, and a plurality of fasteners extends through the corresponding second holding holes to engage the corresponding installation holes.
